(19) United States
(12) Patent Application Publication
(10) Pub. No.: US 2025/0351670 A1
(43) Pub. Date: Nov. 13, 2025

(54) LIGHT EMITTING DEVICE, DISPLAY DEVICE INCLUDING THE SAME, AND ELECTRONIC DEVICE INCLUDING THE SAME

(71) Applicant: Samsung Display Co., Ltd., Yongin-si (KR)

(72) Inventors: Seul Ong KIM, Yongin-si (KR); PILGU KANG, Yongin-si (KR); JIYOUNG SONG, Yongin-si (KR); JIMYOUNG YE, Yongin-si (KR); Jae Hoon HWANG, Yongin-si (KR)

(21) Appl. No.: 19/202,418

(22) Filed: May 8, 2025

(30) Foreign Application Priority Data
May 10, 2024 (KR) 10-2024-0062102

(51) Int. Cl. H10K 50/19; H10K 59/35; H10K 102/00

(52) U.S. Cl. CPC H10K 50/19; H10K 59/353; H10K 2102/351

(57) ABSTRACT

A light-emitting device includes: a first electrode; a second electrode facing the first electrode; and a light emitting layer between the first electrode and the second electrode, wherein the light emitting layer includes a first light emitting layer to emit light at a wavelength between 445 nm and 465 nm, and a fourth light emitting layer to emit light at a wavelength between 520 nm and 540 nm, and the wavelength at which a light emission spectrum at a front is at a maximum is different from a wavelength at which a light emission spectrum at a 45 degree side angle is at a maximum.

### CROSS-REFERENCE TO RELATED APPLICATION

The present application claims priority to and the benefit of Korean Patent Application No. 10-2024-0062102, filed on May 10, 2024, in the Korean Intellectual Property Office, the entire content of which is hereby incorporated by reference.

### BACKGROUND

### 1. Field

Embodiments of the present disclosure relate to a light-emitting device, a display device including the same, and an electronic device including the same.

### 2. Description of the Related Art

A light-emitting device includes an anode, a cathode, and a light-emitting layer between them, and excitons generated holes injected from the anode and electrons injected from the cathode being combined in the light-emitting layer are changed to a ground state from an excited state, thereby releasing energy to emit light.

Because the light-emitting device may be driven with low voltage, it may be configured to be lightweight and thin, and may have excellent characteristics such as viewing angle, contrast, and response speed, a range of applications thereof is increasing from a personal portable device to a television (TV).

### SUMMARY

Embodiments of the present disclosure provide a light-emitting device to improve a color matching ratio and efficiency, and a display device including the same.

An embodiment of the present disclosure provides a light-emitting device including: a first electrode; a second electrode facing the first electrode; and a light emitting layer between the first electrode and the second electrode, wherein the light emitting layer includes a first light emitting layer to emit light at a wavelength between 445 nm and 465 nm, and a fourth light emitting layer to emit light at a wavelength between 520 nm and 540 nm, and a wavelength at which a light emission spectrum at a front is at a maximum is different from a wavelength at which a light emission spectrum at a 45 degree side angle is at a maximum.

A difference between the wavelength at which the light emission spectrum at the front is at the maximum and the wavelength at which the light emission spectrum at the 45 degree side angle is at the maximum may be equal to or less than 5 nm.

The wavelength at which the light emission spectrum at the 45 degree side angle is at the maximum may be shorter than the wavelength at which the light emission spectrum at the front is at the maximum.

The light-emitting device may further include a second light emitting layer to emit light at a wavelength between 445 nm and 465 nm, and a third light emitting layer to emit light at a wavelength between 445 nm and 465 nm.

The second light emitting layer and the third light emitting layer may be between the first light emitting layer and the fourth light emitting layer.

The light-emitting device may further include a first hole transport layer between the first light emitting layer and the first electrode, wherein the thickness of the first hole transport layer may be 150 Å to 250 Å.

The light-emitting device may further include a second hole transport layer between the first light emitting layer and the second light emitting layer, wherein the thickness of the second hole transport layer may be 450 Å to 550 Å.

The light-emitting device may further include a third hole transport layer between the second light emitting layer and the third light emitting layer, wherein the thickness of the third hole transport layer may be 500 Å to 600 Å.

The light-emitting device may further include a fourth hole transport layer between the third light emitting layer and the fourth light emitting layer, wherein the thickness of the fourth hole transport layer may be 250 Å to 350 Å.

The wavelength at which the light emission spectrum at the front is at the maximum may be 455 nm to 484 nm.

The wavelength at which the light emission spectrum at the 45 degree side angle is at the maximum may be 450 nm to 458 nm.

Another embodiment of the present disclosure provides a display device including: a color converting panel; and a display panel that overlaps the color converting panel, wherein the display panel includes a first substrate, and light-emitting devices on the first substrate, the color converting panel includes a first color converting layer, a second color converting layer, and a transmitting layer that overlaps the light-emitting devices, the light-emitting device includes a first electrode, a second electrode facing the first electrode, and light emitting layers between the first electrode and the second electrode, the light emitting layer includes a first light emitting layer to emit light at the wavelength between 445 nm and 465 nm, and a fourth light emitting layer to emit light at the wavelength between 520 nm and 540 nm, and the wavelength at which the light emission spectrum at the front becomes the maximum is different from the wavelength at which the light emission spectrum at the 45 degree side angle becomes the maximum.

The first color converting layer, the second color converting layer, and the transmitting layer may include scatterers (e.g., light scatterers).

A difference between the wavelength at which a light emission spectrum at the front is at the maximum and the wavelength at which the light emission spectrum at the 45 degree side angle is at the maximum may be equal to or less than 5 nm.

The color converting panel may further include a blue color filter, and the wavelength at which the light emission spectrum at the 45 degree side angle is at the maximum may be nearer the transmission wavelength of the blue color filter than the wavelength at which the light emission spectrum at the front is at the maximum.

The light-emitting device may further include a second light emitting layer to emit light at the wavelength between 445 nm and 465 nm, and a third light emitting layer to emit light at the wavelength between 445 nm and 465 nm, and the second light emitting layer and the third light emitting layer may be between the first light emitting layer and the fourth light emitting layer.

The display device may further include a first hole transport layer between the first light emitting layer and the first electrode, wherein the thickness of the first hole transport layer may be 150 Å to 250 Å.

The display device may further include a second hole transport layer between the first light emitting layer and the second light emitting layer, wherein the thickness of the second hole transport layer may be 450 Å to 550 Å.

The display device may further include a third hole transport layer between the second light emitting layer and the third light emitting layer, wherein the thickness of the third hole transport layer may be 500 Å to 600 Å.

The display device may further include a fourth hole transport layer between the third light emitting layer and the fourth light emitting layer, wherein the thickness of the fourth hole transport layer may be 250 Å to 350 Å.

According to embodiments, the light-emitting device that improves the color matching ratio and efficiency and the display device including the same may be provided.

According to embodiments, an electronic device includes the light-emitting device as described herein.

The electronic device may be a smartphone, a television, a monitor, a tablet, an electric vehicle, a mobile phone, a tablet personal computer (PC), a mobile communication terminal, an electronic notebook, an electronic book, a portable multimedia player (P MP), a navigation device, an ultra-mobile PC (UMPC), a laptop computer, a billboard, an Internet of Things (IoT) device, a smartwatch, a watch phone, and/or a head-mounted display (HMD).

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a cross-sectional view of a display device according to an embodiment.

FIG. 2 is a cross-sectional view of a display device according to an embodiment.

FIG. 3 is a cross-sectional view showing a stacked structure of a light-emitting device LED according to an embodiment.

FIG. 4 is a graph showing a light emission spectrum of a light-emitting device according to an embodiment.

FIG. 5 is a cross-sectional view showing a structure of a display device according to an embodiment.

### DETAILED DESCRIPTION

The subject matter of the present disclosure will be described more fully hereinafter with reference to the accompanying drawings, in which embodiments of the disclosure are shown. As those skilled in the art would realize, the described embodiments may be modified in various suitable different ways, all without departing from the spirit or scope of the present disclosure.

Parts that are irrelevant to the description may be omitted to clearly describe the subject matter of the present disclosure, and the same elements will be designated by the same reference numerals throughout the specification.

The size and thickness of each configuration shown in the drawings may be arbitrarily shown for better understanding and ease of description, but the present disclosure is not limited thereto. The thickness of layers, films, panels, regions, and/or the like may be enlarged for clarity. The thicknesses of some layers and areas may be exaggerated for convenience of explanation.

It will be understood that when an element such as a layer, film, region, or substrate is referred to as being “on” another element, it can be directly on the other element or intervening elements may also be present. In embodiments, when an element is referred to as being “directly on” another element, there are no intervening elements present. The word “on” or “above” means on or below the object portion, and does not necessarily mean on the upper side of the object portion based on a gravitational direction.

Unless explicitly described to the contrary, the words “include” and “comprise”, and variations such as “includes,” “including,” “comprises,” or “comprising”, will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

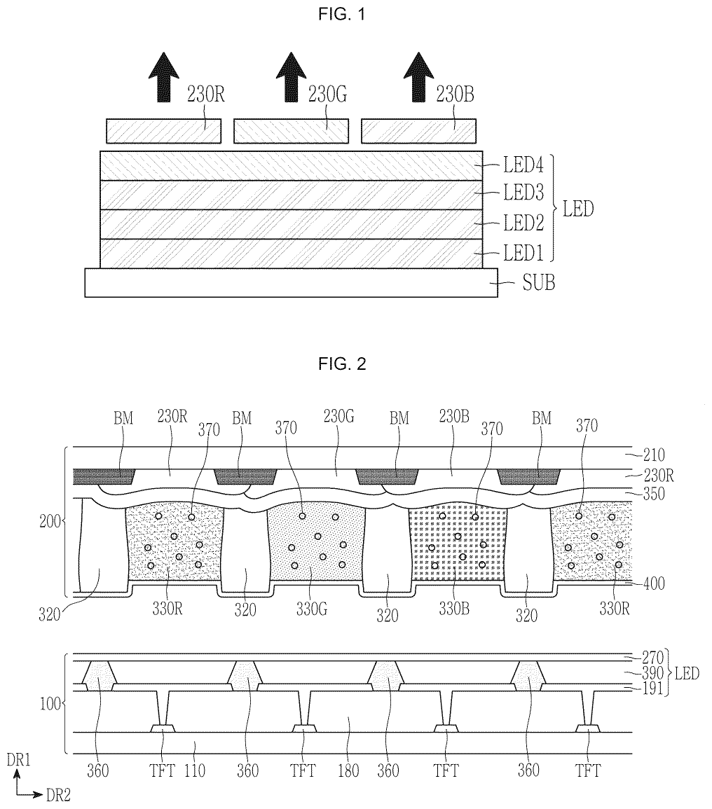

FIG. 1 shows a cross-sectional view of a display device according to an embodiment. Referring to FIG. 1, the display device may include a substrate SUB, a light-emitting device LED on the substrate SUB and including a first light-emitting device LED1, a second light-emitting device LED2, a third light-emitting device LED3, and a fourth light-emitting device LED4, and color filters 230R, 230G, and 230B on the light-emitting device LED. The color filters 230R, 230G, and 230B may be a red color filter, a green color filter, and a blue color filter, respectively. Some of the light-emitting devices LED1, LED2, LED3, and LED4 may emit blue light, and others thereof may emit green light. The first light-emitting device LED1, the second light-emitting device LED2, and the third light-emitting device LED3 from among the light-emitting devices LED1, LED2, LED3, and LED4 may emit blue light, and the fourth light-emitting device LED4 may emit green light. A laminate of the first light-emitting device LED1, the second light-emitting device LED2, the third light-emitting device LED3, and the fourth light-emitting device LED4 may emit white light. The foregoing, however, is an example, and the first light-emitting device LED1, the second light-emitting device LED2, the third light-emitting device LED3, and the fourth light-emitting device LED4 may emit blue, green, red, or yellow light.

A laminate of the first light-emitting device LED1, the second light-emitting device LED2, the third light-emitting device LED3, and the fourth light-emitting device LED4 may emit white light. The white light emitted by the laminate of the first light-emitting device LED1, the second light-emitting device LED2, the third light-emitting device LED3, and the fourth light-emitting device LED4 may pass through the color filters 230R, 230G, and 230B and may be discharged as respective colors (e.g., red light, green light, or blue light).

FIG. 2 shows a detailed cross-sectional view of a display device according to the present embodiment. Referring to FIG. 2, the display device may include a display panel 100 and a color converting panel 200.

The display panel 100 may include a first substrate 110, and transistors TFTs and insulating layers 180 on the first substrate 110. A first electrode 191 and a barrier rib 360 may be on the insulating layer 180, and the first electrode 191 may be provided in an opening of the barrier rib 360 and may be connected to the transistor TFT. In embodiments, the transistor TFT may include a semiconductor layer, a source electrode and a drain electrode connected to the semiconductor layer, and a gate electrode insulated (e.g., electrically insulated) from the semiconductor layer. A second electrode 270 may be on the barrier rib 360, and a light-emitting device layer 390 may be between the first electrode 191 and the second electrode 270. The first electrode 191, the second electrode 270, and the light-emitting device layer 390 may configure the light-emitting device LED. The light-emitting device LED may be the laminate of the light-emitting devices LED1, LED2, LED3, and LED4 as described above with reference to FIG. 1. In embodiments, the light-emitting device LED may include the light-emitting devices LED1, LED2, LED3, and LED4 that emit different colors of light.

The barrier rib 360 may include a black material and may prevent or reduce mixture of colors between the neighboring light-emitting device LED. The foregoing, however, is an example, and the barrier rib 360 may not include the black material.

The color converting panel 200 may include a second substrate 210 and a light blocking member BM on the second substrate 210. The light blocking members BM may include openings. The first color filter 230R, the second color filter 230G, and the third color filter 230B may be provided in the openings of the light blocking members BM. The first color filter 230R may be a red color filter, the second color filter 230G may be a green color filter, and the third color filter 230B may be a blue color filter. The foregoing, however, is an example, and the present disclosure is not limited thereto. FIG. 2 shows the configuration of the light blocking members BM, and the laminate in which the first color filter 230R, the second color filter 230G, and the third color filter 230B are stacked may be provided instead of the light blocking members BM in an embodiment.

A planarizing layer 350 may be on the first color filter 230R, the second color filter 230G, and the third color filter 230B. The planarizing layer 350 may prevent the color filter 230, the color converting layer, and the transmitting layer from directly contacting each other (or reduce an occurrence, likelihood, or degree of such contact), and may planarize a surface of the color filter 230. The planarizing layer 350 may be omitted depending on embodiments.

Banks 320 may be on the planarizing layer 350. The banks 320 may be spaced apart from each other with openings therebetween, and the respective openings may overlap the color filters 230R, 230G, and 230B in a direction that is perpendicular (e.g., substantially perpendicular) to the first substrate 110.

A red color converting layer 330R, a green color converting layer 330G, and a transmitting layer 330B may be provided in regions among the banks 320 that are spaced apart from each other. A capping layer 400 may be on the red color converting layer 330R, the green color converting layer 330G, and the transmitting layer 330B.

The red color converting layer 330R may convert the supplied blue light into red light. The green color converting layer 330G may convert the supplied blue light into green light. The red color converting layer 330R and the green color converting layer 330G may include quantum dots.

The quantum dots will now be described in more detail.

In the present specification, the quantum dots (which may also be referred to as semiconductor nanocrystals) may include a Group II-VI compound, a Group III-V compound, a Group IV-VI compound, a Group IV element or compound, a Group I-III-VI compound, a Group II-III-VI compound, a Group I-II-IV-VI compound, or combinations thereof.

The Group II-VI compound may be selected from among binary element compounds including CdSe, CdTe, ZnS, ZnSe, ZnTe, ZnO, HgS, HgSe, HgTe, MgSe, MgS, and mixtures thereof; ternary element compounds including AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and quaternary element compounds including HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. The Group II-VI compound may further include a Group III metal.

The Group III-V compound may be selected from among binary element compounds including GaN, GaP, GaAs, GaSb, AlN, AlP, AlAs, AlSb, InN, InP, InAs, InSb, and mixtures thereof; ternary element compounds including GaNP, GaNAs, GaNSb, GaP As, GaPSb, AlNP, AlNAs, AlNSb, AlPAs, AlPSb, InGaP, InNP, InNAs, InNSb, InPAs, InZnP, InPSb, and mixtures thereof; and quaternary element compounds including GaAlNP, GaAlNAs, GaAlNSb, GaAlPAS, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof. The Group III-V compound may further include a Group II metal (e.g., InZnP).

The Group IV-VI compound may be selected from among binary element compounds including SnS, SnSe, SnTe, PbS, PbSe, PbTe, and mixtures thereof; ternary element compounds including SnSeS, SnSeTe, SnSTe, PbSeS, PbSeTe, PbSTe, SnPbS, SnPbSe, SnPbTe, and mixtures thereof; and quaternary element compounds including SnPbSSe, SnPbSeTe, SnPbSTe, and mixtures thereof.

The Group IV element or compound may be selected from among unitary elements including Si (e.g., elemental Si), Ge (elemental Ge), and combinations thereof; and binary element compounds including SiC, SiGe, and combinations thereof, and is not limited thereto.

The Group I-III-VI compound may include CuInSe₂, CuInS₂, CuInGaSe, and/or CuInGaS, and is not limited thereto. The Group I-II-IV-VI compound may include CuZnSnSe and/or CuZnSnS, and is not limited thereto. The Group IV element or compound may be selected from among the unitary elements including Si (e.g., elemental Si), Ge (e.g., elemental Ge), and combinations thereof; and the binary element compounds including SiC, SiGe, and combinations thereof, and is not limited thereto.

The Group II-III-VI compound may be selected from among ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and combinations thereof, and is not limited thereto.

The Group I-II-IV-VI compound may be selected from CuZnSnSe and CuZnSnS, and is not limited thereto.

In an embodiment, the quantum dots may not include cadmium (e.g., the quantum dots may be free of cadmium). The quantum dots may include a semiconductor nanocrystal based on the Group III-V compound including indium and phosphorus. The Group III-V compound may further include zinc. The quantum dots may include a semiconductor nanocrystal based on the Group II-VI compound including a chalcogen (e.g., sulfur, selenium, tellurium, or combinations thereof) and zinc.

Regarding the quantum dots, the above-described binary element compounds, the tertiary element compounds, and/or the quaternary compounds may exist in the particles having uniform (e.g., substantially uniform) concentration, or may exist in the same particles having a concentration distribution partially divided into some states. Further, they may have a core/shell structure where one quantum dot surrounds another quantum dot. An interface between the core and the shell may have a concentration gradient such that a concentration of an element existing in the shell is gradually reduced along a direction toward a center of the core.

In some embodiments, the quantum dot may have a core/shell structure including a core including the above-described nanocrystal and a shell surrounding the core. The shell of the quantum dot may function as a protective layer for maintaining the semiconductor characteristic by preventing or reducing chemical denaturation of the core and/or a charging layer for providing an electrophoretic characteristic to the quantum dot. The shell may be a single layer or a multilayer. An interface between the core and the shell may have a concentration gradient such that a concentration of an element existing in the shell is gradually reduced along a direction toward a center of the core. Examples of the shell of the quantum dots may include a metallic and/or non-metallic oxide, a semiconductor compound, or a combination thereof.

For example, examples of the metallic and/or non-metal oxide may include binary element compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; and/or tertiary element compounds such as MgAl₂O₄, CoFe₂O₄, NiFe₂O₄, and/or CoMn₂O₄, and the present disclosure is not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, and the present is not limited thereto.

An interface between the core and the shell may have a concentration gradient such that a concentration of an element existing in the shell is gradually reduced along a direction toward a center of the core. The semiconductor nanocrystal may have a structure including one semiconductor nanocrystal core and a multilayered shell surrounding the semiconductor nanocrystal core. In an embodiment, the multilayered shell may have two or more layers, for example, two, three, four, five, or more layers. The two adjacent layers of the shell may have a single composition or different compositions. In the multilayered shell, each layer may have a composition that varies along the radius of the shell.

The quantum dot may have a full width at half maximum (FWHM) of a light emission wavelength spectrum that is equal to or less than about 45 nm, equal to or less than about 40 nm, or, for example, equal to or less than about 30 nm, and it may improve color purity and/or color reproducibility within the foregoing ranges. Light emitted through the quantum dot may be output in all (e.g., substantially all) directions, thereby improving a wide viewing angle.

Regarding the quantum dot, a shell material and a core material may have different energy bandgaps. For example, the energy bandgap of the shell material may be greater than the energy bandgap of the core material. For another example, the energy bandgap of the shell material may be less than the energy bandgap of the core material. The quantum dot may have a multilayered shell. Regarding the multilayered shell, the energy bandgap of an outer layer may be greater than the energy bandgap of an inner layer (e.g., a layer that is nearer to the core). Regarding the multilayered shell, the energy bandgap of the outer layer may be less than the energy bandgap of the inner layer.

The quantum dots may adjust absorption/emission wavelength by adjusting the composition and the size thereof. The maximum light emitting peak wavelength of the quantum dots may have a wavelength range from ultraviolet to infrared or higher.

The quantum dots may have quantum efficiency of greater than or equal to about 10%, for example, greater than or equal to about 30%, greater than or equal to about 50%, greater than or equal to about 60%, greater than or equal to about 70%, greater than or equal to about 90%, or even about 100%. The quantum dots may have a relatively narrow spectrum. The quantum dots may have the full width at half maximum of the light emission wavelength spectrum, for example, equal to or less than about 50 nm, equal to or less than about 45 nm, equal to or less than about 40 nm, or equal to or less than about 30 nm.

The quantum dots may have a particle size of equal to or greater than about 1 nm and equal to or less than about 100 nm. The particle size may refer to a particle diameter or a diameter which is calculated under the assumption that it has a spherical shape from a 2-D image obtained from, for example, transmission electron microscope analysis. The quantum dots may have a particle size of about 1 nm to about 20 nm, for example, equal to or greater than 2 nm, equal to or greater than 3 nm, or equal to or greater than 4 nm, and equal to or less than 50 nm, equal to or less than 40 nm, equal to or less than 30 nm, equal to or less than 20 nm, equal to or less than 15 nm, or equal to or less than 10 nm. A shape of the quantum dots may not be specifically limited. For example, the shape of the quantum dots may include a sphere (e.g., generally a sphere), a polyhedron, a pyramid, a multipod, a square, a cuboid, a nanotube, a nanorod, a nanowire, a nanosheet, or a combination thereof, and is not limited thereto.

The quantum dots may be commercially available and/or may be suitably or appropriately synthesized. When the quantum dots are colloid-synthesized, the particle sizes may be relatively freely controlled and also uniformly (e.g., substantially uniformly) controlled.

The quantum dot may include an organic ligand (e.g., having a hydrophobic residue and/or a hydrophilic residue). The organic ligand residue may be combined to the surface of the quantum dot. The organic ligand may include RCOOH, RNH₂, R₂NH, R₃N, RSH, R₃PO, R₃P, ROH, RCOOR, RPO(OH)₂, RHPOOH, R₂POOH, or combinations thereof, and in embodiments, R may independently be a C3 to C40 substituted or unsubstituted aliphatic hydrocarbon group such as a C3 to C40 (e.g., C5 to C24) substituted or unsubstituted alkyl group, or a substituted or unsubstituted alkenyl group, a C6 to C40 (e.g., C6 to C20) substituted or unsubstituted aromatic hydrocarbon group such as a C6 to C40 substituted or unsubstituted aryl group, or a combination thereof.

Examples of the organic ligand may include thiol compounds such as methane thiol, ethane thiol, propane thiol, butane thiol, pentane thiol, hexane thiol, octane thiol, dodecane thiol, hexadecane thiol, octadecane thiol, and/or benzyl thiol; amines such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, and/or trioctylamine; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and/or benzoic acid; phosphine compounds such as methyl phosphine, ethyl phosphine, propyl phosphine, butyl phosphine, pentyl phosphine, octyl phosphine, dioctyl phosphine, tributyl phosphine, or trioctyl phosphine; phosphine compounds and/or their oxide compounds such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, trioctyl phosphine oxide, diphenyl phosphine, a triphenyl phosphine compound and/or oxide compounds thereof, C5 to C20 alkyl phosphinic acids such as hexylphosphinic acid, octylphosphinic acid, dodecanephosphinic acid, tetradecanephosphinic acid, hexadecanephosphinic acid, octadecanephosphinic acid, and C5 to C20 alkyl phosphonic acids, and are not limited thereto. The quantum dot may include the organic ligand alone or as a mixture of at least one kind. The hydrophobic organic ligand may not include a photopolymerizable residue (e.g., an acrylate or methacrylate).

The red color converting layer 330R, the green color converting layer 330G, and the transmitting layer 330B may include scatterers 370 (e.g., light scatterers 370). The scatterers 370 may be at least one selected from among SiO₂, BaSO₄, Al₂O₃, ZnO, ZrO₂, and TiO₂. The scatterers may scatter the light discharged by the light-emitting device layer 390 to increase luminous efficiency.

However, the red color converting layer 330R, the green color converting layer 330G, and the transmitting layer 330B include the scatterers, so the spectrum may be suitably or appropriately controlled to increase the color matching ratio of the light-emitting device LED. The light-emitting device and the display device may improve the color matching ratio by suitably or appropriately adjusting a frontal spectrum and a lateral spectrum of the light-emitting device in the display device including scatterers (e.g., light scatterers).

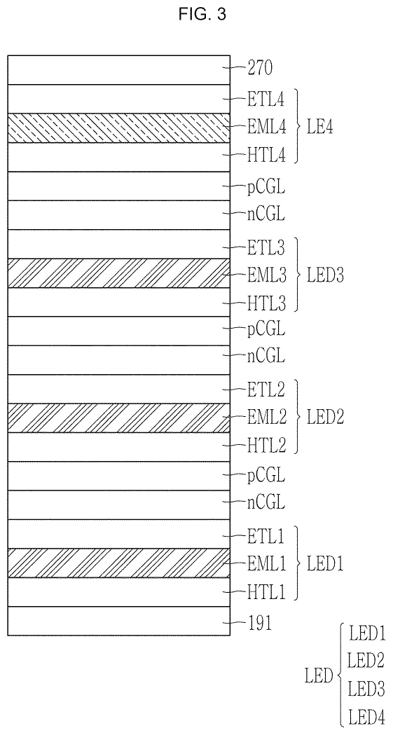

A light-emitting device according to an embodiment will now be described with reference to drawings. FIG. 3 is a cross-sectional view showing a stacked structure of a light-emitting device LED according to an embodiment. Referring to FIG. 3, the light-emitting device may include light-emitting devices LED1, LED2, LED3, and LED4 between the first electrode 191 and the second electrode 270.

As shown in FIG. 3, the respective light-emitting devices LED1, LED2, LED3, and LED4 may include a hole transport layer HTL, a light emitting layer EML, and an electron transport layer ETL. For example, the first light-emitting device LED1 may include a first hole transport layer HTL1, a first light emitting layer EML1, and a first electron transport layer ETL1. In embodiments, the second light-emitting device LED2 may include a second hole transport layer HTL2, a second light emitting layer EML2, and a second electron transport layer ETL2, the third light-emitting device LED3 may include a third hole transport layer HTL3, a third light emitting layer EML3, and a third electron transport layer ETL3, and the fourth light-emitting device LED4 may include a fourth hole transport layer HTL4, a fourth light emitting layer EML4, and a fourth electron transport layer ETL4. An nCGL layer and a pCGL layer may be between the respective light-emitting devices LED1, LED2, LED3, and LED4. In embodiments, an electron blocking layer may be between the hole transport layer HTL and the light emitting layer EML, and a hole blocking layer may be between the electron transport layer ETL and the light emitting layer EML. Other layers that are not shown in FIG. 3 may be therebetween.

As described above, the first light emitting layer EML1, the second light emitting layer EML2, and the third light emitting layer EML3 may emit blue light, and the fourth light emitting layer EML4 may emit green light.

Regarding the light-emitting device, a wavelength at which a light emission spectrum of the light-emitting device at the front reaches a maximum may be different from a wavelength at which a light emission spectrum is a maximum on a side at a 45 degree angle.

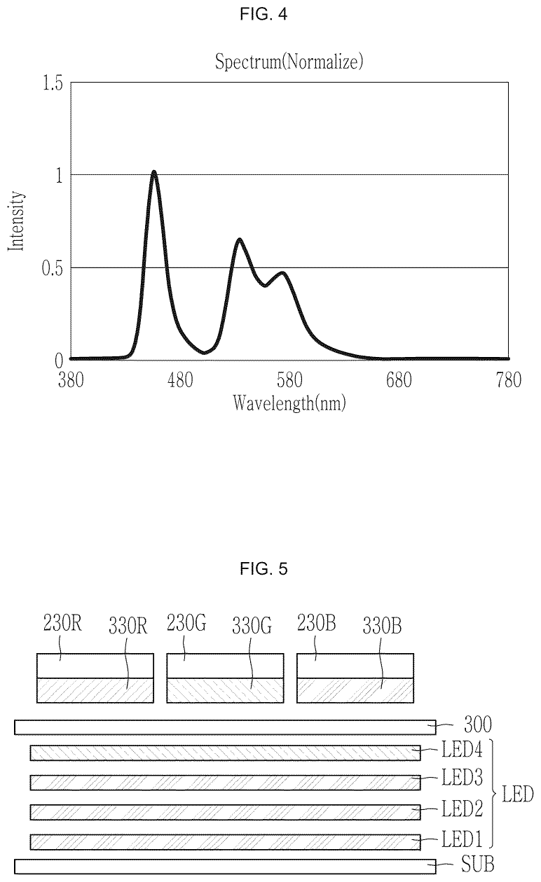

FIG. 4 shows a light emission spectrum of a light-emitting device according to an embodiment. Regarding the light emission spectrum shown in FIG. 4, the wavelength at which the light emission spectrum is maximized, for example, the wavelength when the intensity is 1 in FIG. 4, may be referred to as the wavelength at which the light emission spectrum of the light-emitting device is at the maximum.

Regarding the light-emitting device and the display device including the same, the wavelength at which the light emission spectrum on the side is at the maximum may be shorter than the wavelength at which the light emission spectrum at the front is at the maximum.

When the wavelength at which the light emission spectrum at the 45 degree side angle is at the maximum is shorter than the wavelength at which the light emission spectrum at the front is at the maximum, the color matching ratio may be improved and efficiency may be increased by correcting the light scattered by the scatterers included in the display device.

Thicknesses of the respective layers configuring the light-emitting device may be adjusted and deduced (e.g., determined) so that the wavelength at which the light emission spectrum on the side of 45 degrees is at the maximum may be shorter than the wavelength at which the light emission spectrum at the front is at the maximum. For example, the thickness of the hole transport layer HTL may be suitably or appropriately adjusted and deduced (e.g., determined).

For example, the light-emitting device and the display device including the same may include a light emitting layer to emit light having the wavelength of 445 nm to 465 nm and a light emitting layer to emit light having the wavelength of 520 nm to 540 nm, and the wavelength at which the light emission spectrum on the side of 45 degrees is at the maximum may be shorter than the wavelength at which the light emission spectrum at the front is at the maximum. In embodiments, the color matching ratio and efficiency may be obtained by correcting the light scattered by the scatterers included in the display device.

For example, regarding the display device including the light-emitting device according to the present embodiment, the wavelength at which the light emission spectrum at the front is at the maximum may be different from the wavelength at which the light emission spectrum on the side of 45 degrees is at the maximum. In more detail, a difference between the wavelength at which the light emission spectrum at the front is at the maximum and the wavelength at which the light emission spectrum on the side of 45 degrees may be within 5 nm. In an embodiment, the wavelength at which the light emission spectrum on the side is at the maximum may be shorter than the wavelength at which the light emission spectrum at the front of the display device is at the maximum. The foregoing, however, is an example, to which the present disclosure is not limited.

Regarding the display device according to the present embodiment, the wavelength at which the light emission spectrum on the side of 45 degrees is at the maximum may further approach (e.g., may be closer to) the transmission wavelength of the blue color filter or the green color filter than the wavelength at which the light emission spectrum at the front is at the maximum. For example, when the transmission wavelength of the blue color filter is 453 nm, the wavelength at which the light emission spectrum on the side of 45 degrees is at the maximum may be nearer 453 nm than the wavelength at which the light emission spectrum is at the maximum. In embodiments, when the transmission wavelength of the green color filter is 534 nm, the wavelength at which the light emission spectrum at the 45 degree side angle is at the maximum may be nearer 543 nm than the wavelength at which the light emission spectrum at the front is at the maximum.

An effect of embodiments of the present disclosure will now be further described through an experimental example.

Table 1 expresses a stacked configuration of a light-emitting device according to an embodiment. Table 1 shows materials, thicknesses, and doping concentrations included in respective layers configuring the first light-emitting devices LED1, LED2, LED3, and LED4. The foregoing, however, is an example, to which the present disclosure is not limited.

TABLE 1

| | | | | Doping |
|---|---|---|---|---|
| | | | Thicknesses | concentrations |
| Layers | | Material names | (Å) | (%) |
| Second electrodes | | CPL | 500 | |
| | | AgMg | 100 | 10 |
| | | Yb | 1 | |
| LED4 | Fourth electron | TPM-TAZ:Ir (mppy)3 | 520 | 50 |
| | transport layer | | | |
| | (ETL) | | | |
| | Fourth light | PCz-BFP:Irppy | 280 | 9 |
| | emitting layer | | | |
| | Fourth electron | TCTA | 50 | |
| | blocking layer | | | |
| | Fourth hole | TAPC | 300 | |
| | transport layer HTL | | | |
| | Fourth hole | TAPC:HATCN | 70 | 5 |
| | injection layer (HIL) | | | |
| nCGL | | BCP + Li | 40 | 2 |
| LED3 | Third electron | TPM-TAZ:Liq | 100 | 50 |
| | transport layer | | | |
| | (ETL) | | | |
| | Third hole blocking | T2T | 50 | |
| | layer | | | |
| | Third light emitting | Host:Dopant | 150 | 2 |
| | layer | | | |
| | Third electron | TCTA | 75 | |
| | blocking layer | | | |
| | Third hole transport | TAPC | 550 | |
| | layer HTL | | | |
| | Third hole injection | TAPC:HATCN | 70 | 5 |
| | layer (HIL) | | | |
| nCGL | | BCP + Li | 40 | 2 |
| LED2 | Second electron | TPM-TAZ:Liq | 100 | 50 |
| | transport layer | | | |
| | (ETL) | | | |
| | Second hole | T2T | 50 | |
| | blocking layer | | | |
| | Second light | Host:Dopant | 150 | 2 |
| | emitting layer | | | |
| | Second electron | TCTA | 75 | |
| | blocking layer | | | |
| | Second hole | TAPC | 500 | |
| | transport layer HTL | | | |
| | Second hole | TAPC:HATCN | 70 | 5 |
| | injection layer (HIL) | | | |
| nCGL | | BCP + Li | 40 | 2 |
| LED1 | First electron | TPM-TAZ:Liq | 100 | 50 |
| | transport layer | | | |
| | (ETL) | | | |
| | First hole blocking | T2T | 50 | |
| | layer | | | |
| | First light emitting | Host:Dopant | 150 | 2 |
| | layer | | | |
| | First electron | TCTA | 75 | |
| | blocking layer | | | |
| | First hole transport | TAPC | 200 | |
| | layer HTL | | | |
| | First hole injection | TAPC:HATCN | 50 | 4 |
| | layer (HIL) | | | |

| | | |
|---|---|---|
| First electrodes | ITO/Ag/ITO | 80/1000/80 |

The materials written in Table 1 represent material names, and chemical formulae of some of the materials are expressed below. The materials of which chemical formulae are not shown correspond to general titles of the corresponding materials. Some chemical formulae are written according to the material names, and some other chemical formulae provide the layers on which the compounds of the corresponding chemical formulae are provided.

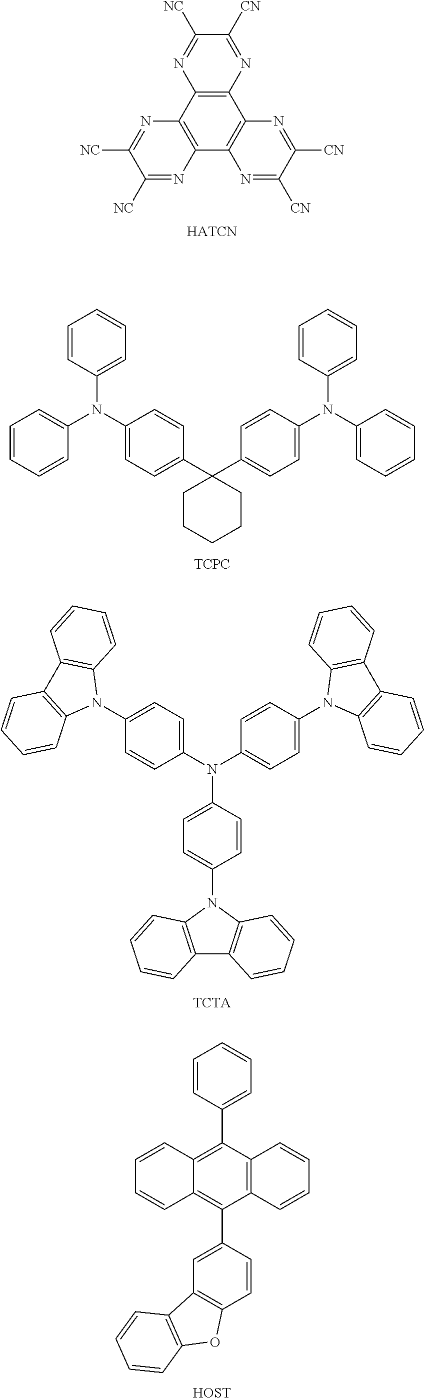

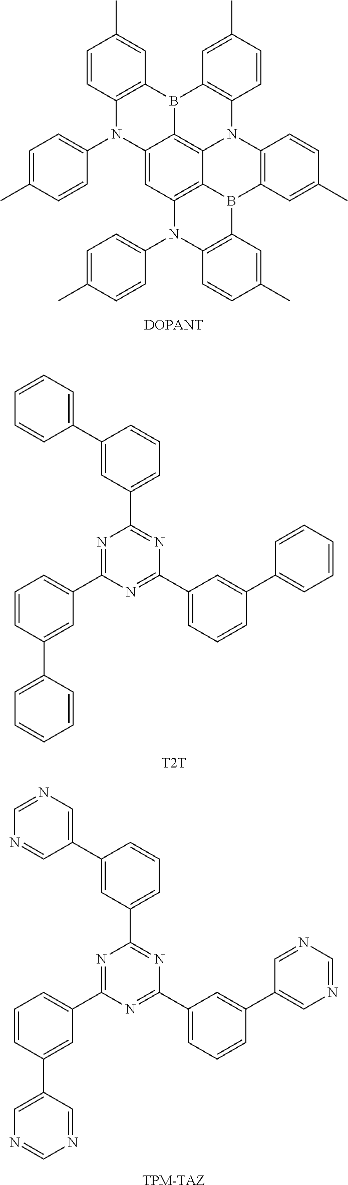

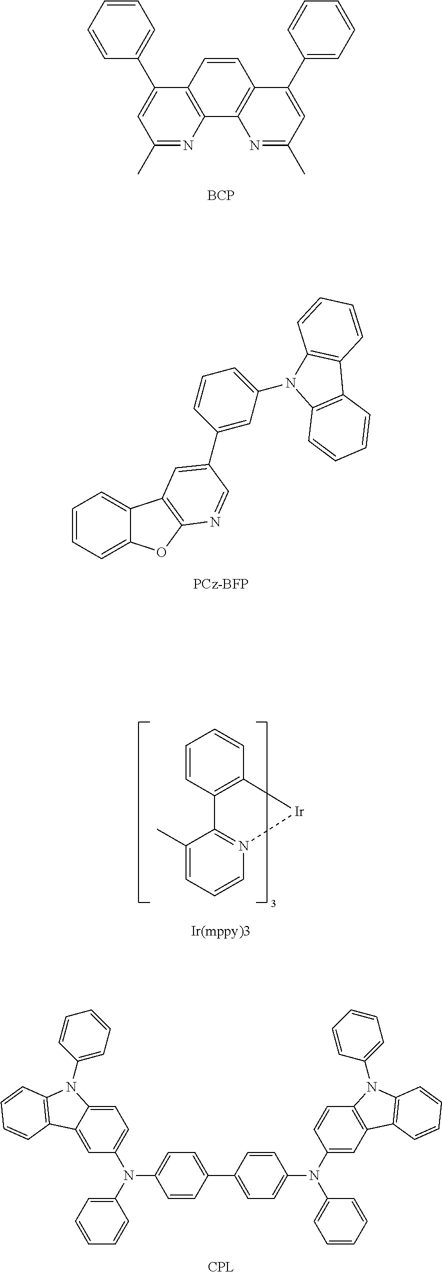

Regarding the light-emitting device having the stacked structure, the hole transport layers HTL of the first light-emitting device LED1, the second light-emitting device LED3, the third light-emitting device LED3, and the fourth light-emitting device LED4 may be sequentially stacked by making the thicknesses thereof different, to thus measure efficiency at the front and on the side, and measured results may be shown in Table 2. In embodiments, the wavelengths at which the wavelength spectrum is at MAX (e.g., Amax or the maximum) in the respective light-emitting devices are shown in Table 2. The first light-emitting device, the second light-emitting device, and the third light-emitting device LED1, LED2, and LED3 may emit blue light, and the fourth light-emitting device LED4 may emit green light.

TABLE 2

| | | | Efficiency | Radiance | Blue | Green |
|---|---|---|---|---|---|---|
| Stack | HTL | Angles | (cd/A) | (W/m2/sr) | λmax | λmax |
| 1 | 150 Å | Front | 6.7 | 7.3 | 455 | None |
| | | (0 degrees) | | | | |
| | | Side | 3.7 | 4.8 | 452 | None |
| | | (45 degrees) | | | | |
| | 200 Å | Front | 7.1 | 6.4 | 458 | None |
| | | (0 degrees) | | | | |
| | | Side | 4.2 | 5.0 | 453 | None |
| | | (45 degrees) | | | | |
| | 250 Å | Front | 7.4 | 5.4 | 484 | None |
| | | (0 degrees) | | | | |
| | | Side | 4.6 | 4.9 | 456 | None |
| | | (45 degrees) | | | | |
| 2 | 450 Å | Front | 16.5 | 17.1 | 461 | None |
| | | (0 degrees) | | | | |
| | | Side | 8.2 | 13.4 | 452 | None |
| | | (45 degrees) | | | | |
| | 500 Å | Front | 17.1 | 14.9 | 479 | None |
| | | (0 degrees) | | | | |
| | | Side | 9.0 | 13.5 | 453 | None |
| | | (45 degrees) | | | | |
| | 550 Å | Front | 17.6 | 13.0 | 484 | None |
| | | (0 degrees) | | | | |
| | | Side | 9.7 | 13.0 | 456 | None |
| | | (45 degrees) | | | | |
| 3 | 500 Å | Front | 21.9 | 21.0 | 477 | None |
| | | (0 degrees) | | | | |
| | | Side | 11.4 | 18.7 | 452 | None |
| | | (45 degrees) | | | | |
| | 550 Å | Front | 23.1 | 19.4 | 481 | None |
| | | (0 degrees) | | | | |
| | | Side | 12.1 | 18.9 | 453 | None |
| | | (45 degrees) | | | | |
| | 600 Å | Front | 24.2 | 17.9 | 484 | None |
| | | (0 degrees) | | | | |
| | | Side | 12.7 | 18.4 | 458 | None |
| | | (45 degrees) | | | | |
| 4 | 250 Å | Front | 67.8 | 29.5 | 474 | 579 |
| | | (0 degrees) | | | | |
| | | Side | 78.7 | 29.3 | 450 | 535 |
| | | (45 degrees) | | | | |
| | 300 Å | Front | 62.5 | 27.6 | 478 | 579 |
| | | (0 degrees) | | | | |
| | | Side | 76.5 | 29.4 | 453 | 537 |
| | | (45 degrees) | | | | |
| | 350 Å | Front | 57.8 | 25.9 | 482 | 580 |
| | | (0 degrees) | | | | |
| | | Side | 73.7 | 29.0 | 455 | 538 |
| | | (45 degrees) | | | | |

Referring to Table 2, it can be seen that when the thickness of the first hole transport layer is 200 angstroms, the thickness of the second hole transport layer is 500 angstroms, and the thickness of the third hole transport layer is 600 angstroms, the maximum wavelength of the wavelength spectrum at the 45 degree side angle is 453 nm. In the thickness range of the respective hole transport layers shown in Table 2, it may be found that radiance at the 45 degree side angle is improved compared to the radiance at the front.

For example, it may be found that the radiance at the 45 degree side angle is further improved than the radiance at the front within the thickness range of the hole transport layers HTL of the first light-emitting device LED1, the second light-emitting device LED3, the third light-emitting device LED3, and the fourth light-emitting device LED4 expressed in Table 2. Hence, the efficiency and the color matching ratio of the display device may be improved when applying the light-emitting device to the display device.

Table 3 expresses measurements of the efficiency and color matching ratio when the light-emitting device shown in Table 2 is applied to the display device having the stacked structure of FIG. 5. FIG. 5 shows a structure of a display device according to an embodiment.

A refractive index matching layer 300 may be between the display panel 100 and the color converting panel 200 in the stacked structure of FIG. 5. The display panel 100 may include a first light-emitting device LED1, a second light-emitting device LED3, a third light-emitting device LED3, and a fourth light-emitting device LED4 on the substrate SUB. The color converting panel 200 may include a red color converting layer 330R, a green color converting layer 330G, and a transmitting layer 330B, and may include a red color filter 230R, a green color filter 230G, and a blue color filter 230B that overlap the red color converting layer 330R, the green color converting layer 330G, and the transmitting layer 330B. The transmission wavelength of the red color filter 230R may be 644 nm, the transmission wavelength of the green color filter 230G may be 534 nm, and the transmission wavelength of the blue color filter 230B may be 453 nm.

Regarding the display device shown in FIG. 5, the efficiency and the color matching ratio may be measured by changing the thickness of the hole transport layer HTL of the fourth light-emitting device LED4, and measured results are expressed in Table 3.

TABLE 3

| | | | | | | | | | | | BT2020 |
|---|---|---|---|---|---|---|---|---|---|---|---|
| | | | | | | | | | | White Eff | Color |
| HTL | | | | | | | | | | (Wx 0.28 | matching |
| thickness | Rx | Ry | R_Eff | Gx | Gy | G_Eff | Bx | By | B_Eff | Wy 0.29) | ratios |
| 4 | 0.701 | 0.296 | 9.8 | 0.231 | 0.733 | 46.4 | 0.144 | 0.046 | 5.5 | 19.5 | 89.8% |
| HTL | | | | | | | | | | | |
| 250 | | | | | | | | | | | |
| 4 | 0.702 | 0.296 | 9.9 | 0.231 | 0.733 | 46.2 | 0.144 | 0.047 | 5.6 | 19.6 | 90.1% |
| HTL | | | | | | | | | | | |
| 300 | | | | | | | | | | | |
| 4 | 0.701 | 0.297 | 9.8 | 0.231 | 0.733 | 45.2 | 0.143 | 0.048 | 5.8 | 19.3 | 89.7% |
| HTL | | | | | | | | | | | |
| 350 | | | | | | | | | | | |

Referring to Table 3, it can be seen that the color matching ratio is high when the thickness of the hole transport layer HTL of the fourth light-emitting device LED4 is 300 angstroms.

It has been described above that the radiance on the side of the light-emitting device may be further optimized or improved compared to the radiance at the front by adjusting the thickness of the hole transport layer HTL, and the efficiency and the color matching ratio of the display device are improved. The foregoing, however, is an example, and the radiance on the side may be further optimized or improved compared to the radiance at the front by adjusting the thickness of the other layer and not that of the hole transport layer HTL.

According to embodiments, an electronic device includes the light-emitting device as described herein. The electronic device may be a smartphone, a television, a monitor, a tablet,

an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

While the subject matter of this disclosure has been described in connection with what is presently considered to be practical embodiments, it is to be understood that the disclosure is not limited to the disclosed embodiments, but, on the contrary, is intended to cover various suitable modifications and equivalent arrangements included within the spirit and scope of the appended claims, and equivalents thereof.

What is claimed is:

1. A light-emitting device comprising:
a first electrode;
a second electrode facing the first electrode; and
a light emitting layer between the first electrode and the second electrode,
wherein the light emitting layer comprises:
a first light emitting layer to emit light at a wavelength between 445 nm and 465 nm, and
a fourth light emitting layer to emit light at a wavelength between 520 nm and 540 nm, and
the wavelength at which a light emission spectrum at a front is at a maximum is different from a wavelength at which a light emission spectrum at a 45 degree side angle is at a maximum.

2. The light-emitting device of claim 1, wherein:
a difference between the wavelength at which the light emission spectrum at the front is at the maximum and the wavelength at which the light emission spectrum at the 45 degree side angle is at the maximum is equal to or less than 5 nm.

3. The light-emitting device of claim 1, wherein:
the wavelength at which the light emission spectrum at the 45 degree side angle is at the maximum is shorter than the wavelength at which the light emission spectrum at the front is at the maximum.

4. The light-emitting device of claim 1, wherein:
the light-emitting device further comprises:
a second light emitting layer to emit light at a wavelength between 445 nm and 465 nm, and
a third light emitting layer to emit light at a wavelength between 445 nm and 465 nm.

5. The light-emitting device of claim 4, further comprising:
a first hole transport layer between the first light emitting layer and the first electrode,
wherein the thickness of the first hole transport layer is 150 Å to 250 Å.

6. The light-emitting device of claim 4, further comprising:
a second hole transport layer between the first light emitting layer and the second light emitting layer,
wherein the thickness of the second hole transport layer is 450 Å to 550 Å.

7. The light-emitting device of claim 4, further comprising:
a third hole transport layer between the second light emitting layer and the third light emitting layer,
wherein the thickness of the third hole transport layer is 500 Å to 600 Å.

8. The light-emitting device of claim 4, further comprising:
a fourth hole transport layer between the third light emitting layer and the fourth light emitting layer,
wherein the thickness of the fourth hole transport layer is 250 Å to 350 Å.

9. The light-emitting device of claim 1, wherein:
the wavelength at which the light emission spectrum at the front is at the maximum is 455 nm to 484 nm.

10. The light-emitting device of claim 1, wherein:
the wavelength at which the light emission spectrum at the 45 degree side angle is at the maximum is 450 nm to 458 nm.

11. A display device comprising:
a color converting panel; and
a display panel that overlaps the color converting panel,
wherein the display panel comprises:
a first substrate, and
light-emitting devices on the first substrate,
the color converting panel comprises:
a first color converting layer, a second color converting layer, and a transmitting layer that overlap the light-emitting devices,
the light-emitting device comprises:
a first electrode,
a second electrode facing the first electrode, and
light emitting layers between the first electrode and the second electrode,
the light emitting layer comprises:
a first light emitting layer to emit light at the wavelength between 445 nm and 465 nm, and
a fourth light emitting layer to emit light at the wavelength between 520 nm and 540 nm, and
the wavelength at which the light emission spectrum at the front is at the maximum is different from the wavelength at which the light emission spectrum at the 45 degree side angle becomes the maximum.

12. The display device of claim 11, wherein:
a difference between the wavelength at which the light emission spectrum at the front is at the maximum and the wavelength at which the light emission spectrum at the 45 degree side angle is at the maximum is equal to or less than 5 nm.

13. The display device of claim 11, wherein:
the color converting panel further comprises a blue color filter, and the wavelength at which the light emission spectrum at the 45 degree side angle is at the maximum is nearer the transmission wavelength of the blue color filter than the wavelength at which the light emission spectrum at the front is at the maximum.

14. The display device of claim 11, wherein:
the light-emitting device further comprises:
a second light emitting layer to emit light at the wavelength between 445 nm and 465 nm, and
a third light emitting layer to emit light at the wavelength between 445 nm and 465 nm, and
the second light emitting layer and the third light emitting layer are between the first light emitting layer and the fourth light emitting layer.

15. The display device of claim 14, further comprising:
a first hole transport layer between the first light emitting layer and the first electrode,
wherein the thickness of the first hole transport layer is 150 Å to 250 Å.

16. The display device of claim 14, further comprising:
a second hole transport layer between the first light emitting layer and the second light emitting layer,
wherein the thickness of the second hole transport layer is 450 Å to 550 Å.

17. The display device of claim 14, further comprising:
a third hole transport layer between the second light emitting layer and the third light emitting layer,
wherein the thickness of the third hole transport layer is 500 Å to 600 Å.

18. The display device of claim 14, further comprising:
a fourth hole transport layer between the third light emitting layer and the fourth light emitting layer,
wherein the thickness of the fourth hole transport layer is 250 Å to 350 Å.

19. An electronic device, comprising:
a light-emitting device comprising:
a first electrode;
a second electrode facing the first electrode; and
a light emitting layer between the first electrode and the second electrode,
wherein the light emitting layer comprises:
a first light emitting layer to emit light at a wavelength between 445 nm and 465 nm, and
a fourth light emitting layer to emit light at a wavelength between 520 nm and 540 nm, and
the wavelength at which a light emission spectrum at a front is at a maximum is different from a wavelength at which a light emission spectrum at a 45 degree side angle is at a maximum.

20. The electronic device of claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
